(19) United States
(12) Patent Application Publication
(10) Pub. No.: US 2022/0311203 A1
(43) Pub. Date: Sep. 29, 2022

(54) ELECTROMAGNETIC GAS SPECTROMETER

(71) Applicant: QUINC.TECH INC., San Diego, CA (US)

(72) Inventor: Lee LEMAY, San Diego, CA (US)

(21) Appl. No.: 17/703,989

(22) Filed: Mar. 25, 2022

Related U.S. Application Data
(60) Provisional application No. 63/165,569, filed on Mar. 24, 2021.

(51) Int. Cl. H01S 3/16; G01J 3/02

(52) U.S. Cl. CPC H01S 3/1683; G01J 3/0286; G01J 3/0202; H01S 2302/02

(57) ABSTRACT

Aspects of the present disclosure relate to receiving and emitting Terahertz (THz) electromagnetic radiation via one or more Josephson Junction(s) electronically coupled to an antenna structure. Aspects of the present disclosure further relate to a mechanism and methods to analyze a gas and/or identifying a gas (and/or suspension) based its electromagnetic absorption. Together, THz electromagnetic radiation may be emitted from one or more Josephson Junction emitters (transmitters), passed through a gas/suspension of interest, and non-absorbed THz electromagnetic radiation may be detected from one or more Josephson Junction detectors (receivers).

### BACKGROUND OF THE INVENTION

### Technical Field

The present invention pertains generally to transmission and reception of terahertz radiation, and is more particularly directed towards devices and systems for and methods of fluid/suspension identification based on its electromagnetic absorption.

### Related Art

Currently, detection of trace gases from a mixture is done by a Gas Chromatography (GC) system, which separates out all the different gases in a mixture. The GC system is paired with a second detector, such as a Mass Spectrometer (MS), to allow it to identify individual gases once they are separated. The GC-MS works well but is quite bulky and takes over an hour to analyze a sample.

Functionally, the GC system sends a gaseous sample into a column that is kept at low pressure. In particular, it separates the gaseous sample into its different constituent gases as they pass through the column—interactions with the surface of the column cause different gases to travel at different rates through the columns. A detector at the exit of the column is used to determine what each gas is. Example detectors that are used include flame ionization detectors and mass spectrometry (MS) systems.

GC based systems are technologically mature, but suffer from several drawbacks. For example, they rely on a bulky column that operates under vacuum. The vacuum system requires maintenance. The size of the system and vacuum requirements make portability and field operations difficult. GC systems are also relatively slow in making their measurements. The gases must pass through the columns to achieve separation, an inherently slow process that can take tens of minutes or even hours.

Electromagnetic radiation with frequencies between 300 GHz and 3 THz is commonly referred to as “terahertz radiation”. Sometimes frequencies as high as 10 THz are included in this designation. Of interest here, terahertz radiation naturally excites the rotational and vibrational modes of molecules. When a vibrational or rotational mode of a molecule is excited by electromagnetic radiation, the molecule absorbs some of the energy contained in the electromagnetic wave. However, Terahertz radiation has traditionally been challenging to generate and detect. In recent years, advances in photoconductive antennas (PCAs) and quantum cascade lasers (QCLs) have shown promise in generating and detecting the radiation; however, both technologies have drawbacks.

PCAs are made from semiconductors such as Gallium Arsenide (GaAs) which are biased electrically and then illuminated with an ultra-fast, femtosecond laser pulse. When the laser pulse illuminates the PCA, it emits a fast burst of radiation, lasting for a few picoseconds. Each picosecond burst of radiation contains a broad band of THz frequencies. The femtosecond laser pulse is repeated at MHz frequencies to create a sequence of THz pulses. These pulses are detected by another PCA; the THz pulses and another set of ultra-fast laser pulses are incident on the detector PCA. When both are incident simultaneously, they create a voltage. Because the laser pulse is very short, each measurement is a gated time slice; a sequence of measurements must be made to measure the complete signal, which lasts several picoseconds. A Fourier Transform is then applied to the signal to determine its frequency components. This process is inefficient; the laser itself is inefficient, and the generation of THz radiation is inefficient, for example, a watt of wall plug power may produce a microwatt of THz energy. The PCA can only generate a few microwatts of power. The laser and optical components are bulky, which limits portability and field use. The frequency resolution of this method is limited by the Fourier transform; the resolution is proportional to the number of samples that are taken. It may take several minutes of measurements in order to reach a frequency resolution of a few GHz.

QCLs are lasers that can generate narrowband, high power THz radiation. However, they are not broadly tunable; an advanced tunable QCL may have a tunable bandwidth of 10 GHz. This means that they are not suitable for spectroscopy, which requires the ability to generate frequencies across 100's of GHz to detect and differentiate among different types of molecules.

The present disclosure is directed toward overcoming known problems and problems discovered by the inventor.

### SUMMARY OF THE INVENTION

Aspects of the present disclosure relate to receiving and emitting Terahertz (THz) electromagnetic radiation via one or more Josephson Junction(s) electronically coupled to an antenna structure. Aspects of the present disclosure further relate to a mechanism and methods to analyze a gas and/or identifying a gas (and/or suspension) based its electromagnetic absorption. Together, THz electromagnetic radiation may be emitted from one or more Josephson Junction emitters (transmitters), passed through a gas/suspension of interest, and non-absorbed THz electromagnetic radiation may be detected from one or more Josephson Junction detectors (receivers).

### BRIEF DESCRIPTION OF THE DRAWINGS

FIG. 1 is a schematic diagram of an exemplary Gas Chromatography (GC) system, paired with a Mass Spectrometer (MS).

FIG. 2 is a schematic diagram of an exemplary electromagnetic gas spectrometer, according to one embodiment of the disclosure.

FIG. 3 is a schematic diagram of the exemplary electromagnetic gas spectrometer of FIG. 2 in operation, including a representative input and output signal, when the input signal is applied to a simple compound.

FIG. 4 is a representative output signal of the of the exemplary electromagnetic gas spectrometer of FIG. 2 in operation, when the input signal is applied to a more complex material.

FIG. 5 schematically illustrates the RCSJ model for a Josephson Junction (JJ).

FIG. 6 is a plot that shows the voltage output of a JJ for different DC bias currents with no alternating currents passing through it.

FIG. 7A is a plot shows the voltage output of a JJ for different DC bias currents with an alternating current passing through it.

FIG. 7B is a close up of the left side of the plot of FIG. 7A.

FIG. 7C is a close up of the right side of the plot of FIG. 7A.

FIG. 8A is a schematic diagram of an exemplary THz detector/receiver (or THz emitter/transmitter), according to one embodiment of the disclosure.

FIG. 8B is a schematic diagram of an exemplary THz detector/receiver (or THz emitter/transmitter), according to one embodiment of the disclosure.

FIG. 9 is a schematic diagram of an exemplary THz detector/receiver (or THz emitter/transmitter), according to one embodiment of the disclosure.

FIG. 10 is a schematic diagram of an exemplary THz detector/receiver (or THz emitter/transmitter), according to one embodiment of the disclosure.

FIG. 11 is a schematic diagram (radial view, relative to the gas absorption cell) of an exemplary electromagnetic gas spectrometer, according to one embodiment of the disclosure

FIG. 12 a schematic diagram (axial view, relative to the gas absorption cell) of a detail of the exemplary electromagnetic gas spectrometer of FIG. 11, according to one embodiment of the disclosure.

FIG. 13 is a cutaway back view of an exemplary implementation of an electromagnetic gas spectrometer, according to one embodiment of the disclosure.

FIG. 14 is a front view of the electromagnetic gas spectrometer of FIG. 13, according to one embodiment of the disclosure.

FIG. 15 is a detail back view of the electromagnetic gas spectrometer of FIG. 13, according to one embodiment of the disclosure.

FIG. 16 is a detail cutaway back view of the electromagnetic gas spectrometer of FIG. 13, according to one embodiment of the disclosure.

FIG. 17 is a detail section view (axial view) of a gas absorption cell for the electromagnetic gas spectrometer of FIG. 13, according to one embodiment of the disclosure.

FIG. 18 is a cross-sectional view of the gas absorption cell for the electromagnetic gas spectrometer of FIG. 17, along line A-A, according to one embodiment of the disclosure.

FIG. 19 is a schematic representation of a THz transmission making multiple passes in the gas absorption cell of FIG. 13, according to one embodiment of the disclosure.

FIG. 20 is a schematic representation (axial view) of a THz transmission making multiple passes in the gas absorption cell of FIG. 13, according to one embodiment of the disclosure.

FIG. 21 is a schematic representation (perspective view) of a THz transmission making multiple passes in the gas absorption cell of FIG. 13, according to one embodiment of the disclosure.

FIG. 22 is a schematic representation (alternate perspective view) of a THz transmission making multiple passes in the gas absorption cell of FIG. 13, according to one embodiment of the disclosure.

FIG. 23 is a schematic representation (alternate perspective view) of a THz transmission making multiple passes in the gas absorption cell of FIG. 13, according to one embodiment of the disclosure.

FIG. 24 a schematic diagram of the gas absorption cell of FIG. 13, along with associated plumbing, according to one embodiment of the disclosure.

FIG. 25 is a flow diagram of a method for analyzing a gas using an electromagnetic gas spectrometer, according to one embodiment of the disclosure.

### DETAILED DESCRIPTION

Aspects of the present disclosure relate to receiving and emitting Terahertz (THz) electromagnetic radiation via a Josephson Junction electronically coupled to an antenna. Aspects of the present disclosure further relate to a mechanism and methods to analyze a gas and/or identifying a gas (and/or suspension) based its electromagnetic absorption. Together, THz electromagnetic radiation may be emitted from one or more Josephson Junction emitters, passed through a gas/suspension of interest, and non-absorbed THz electromagnetic radiation may be detected from one or more Josephson Junction detectors (receivers).

Beneficially, aspects of the disclosure may be used to detect and identify the presence of trace gases in mixtures of gases. This may be useful when performing many different scientific analyses. For example, in forensic science, samples from the crime scene are heated and the gases they emit are analyzed to aid the investigation. In petroleum analysis and refinement, gaseous analysis is applied to crude oil exploration, refining, and development of novel petrochemicals. In healthcare, trace volatile organic compounds in the breath, blood, feces, or from the skin have been linked to diseases, and the ability to detect them could serve as a rapid screening technique.

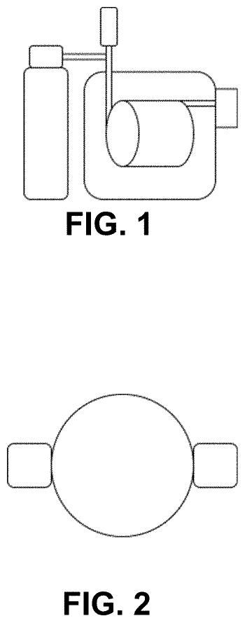

For reference, FIG. 1 is a schematic diagram of an exemplary Gas Chromatography (GC) system 10, paired with a Mass Spectrometer (MS) 15. As discussed above, the GC system 10 will typically include an oven 16, a column 17, a sample injector 18, a gas carrier 19, and a regulator 20, and the MS 15 will include a detector 13. In operation, the GC system 10 separates out all the different gases in a mixture, and then passes each gas through the detector 13 to determine what it is. Also as above. Some principles, particularly related to gas management and subsequent gas analysis are understood to be applicable here in the present disclosure.

FIG. 2 is a schematic diagram of an exemplary electromagnetic gas spectrometer, according to one embodiment of the disclosure. In particular, an exemplary electromagnetic gas spectrometer 100 may generally include a Terahertz (THz) emitter/transmitter 120, a Terahertz (THz) detector/receiver 130, and a gas absorption cell 170. Particular embodiments are discussed in greater detail below.

Science shows that gaseous compounds may naturally absorb one or more particular frequency bands of electromagnetic energy emitted into it, but not others. The disclosed THz electromagnetic gas spectrometer 100 may exploit this phenomena to determine the type of compounds/molecules that are present in a gas. In particular, the THz emitter 120 may be configured to emit desired THz radiation into a gas contained in the gas absorption cell 170, and the THz detector 130 may be configured to receive the THz radiation emitted, or rather the portion that is not absorbed by the gas.

The electromagnetic gas spectrometer works 100 by passing electromagnetic radiation through a gas, and measuring the frequencies that are absorbed by the gas. In particular, when electromagnetic radiation travels through the gas, certain frequencies resonate with the molecular vibrations and rotations of the gas. Energy from the frequencies that resonate are absorbed by the gas. The resonant frequencies are different for different molecules. After the radiation passes through the gas, it is incident on the detector 130, which measures the power/electromagnetic radiation received. By determining which frequencies were absorbed, and in some embodiments, their level of absorption, the electromagnetic gas spectrometer 100 can correlate or otherwise process the data, and identify the gases that are present in the gaseous mixture.

In operation, electromagnetic gas spectrometer 100 may generate THz radiation and measure which frequencies are absorbed. Then it looks up which gas or combinations of gases would create that absorption spectrum. According to one embodiment, electromagnetic gas spectrometer 100 may also estimate the concentration of each detected gas, based on the amount of energy that was absorbed.

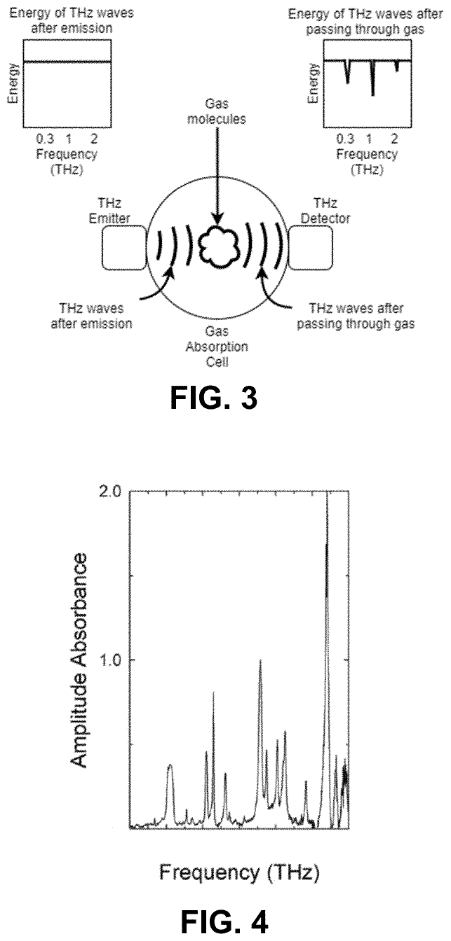

FIG. 3 is a schematic diagram of the exemplary electromagnetic gas spectrometer of FIG. 2 in operation, including a representative input signal (THz transmission) 93 and output signal (THz reception) 95, when the input signal is applied to a simple compound (a gas 91). As above, the electromagnetic gas spectrometer 100 may generally include the Terahertz (THz) emitter/transmitter 120, the Terahertz (THz) detector/receiver 130, and the gas absorption cell 170. Here, the energy of the emitted waves of the THz radiation emitter are shown before and after interacting with the gas molecules of the gas absorption cell 170.

As above, the wavelength/frequency/band of the radiation that is absorbed is dependent upon the structure and composition of the molecule, as well as the state of the molecule—liquid, solid, or gas. In general, a liquid or solid will absorb strongly across a continuous band of wavelengths. In contrast, molecules in a gas at ambient pressure will absorb strongly in one or more bands that are a few GHz wide. The width of the absorption bands is proportional to the pressure of the gas; as the pressure increases, the absorption bands get wider. The location of these absorption frequency bands depends on what the molecule is. For example, ammonia absorbs strongly at 1.18 and 1.23 THz, while water absorbs strongly at 1.1, 1.17 and 1.4 THz. Other molecules absorb strongly at different frequencies based on their atomic composition and structure.

In anticipation of this, the electromagnetic gas spectrometer 100 may advantageously be configured or otherwise limited to emit a particular frequency, a plurality of frequencies, a pattern of frequencies, a range of frequencies, and/or a spectrum of frequencies into the gas 91 contained in the gas absorption cell and to detect which frequencies (if any have been absorbed). Frequency bands may be designed for a particular substance of interest, and/or may be swept over a predetermined range.

FIG. 4 is a representative output signal of the of the exemplary electromagnetic gas spectrometer of FIG. 2 in operation, when the input signal 93 is applied to a more complex material. In particular, a more complex material (gas 91) may result in a more complex absorption profile. For example, trace particles of a known explosive may result in the illustrated absorption profile. Note, here the output signal 95 is displayed as inverted, to show the frequencies absorbed by the gas 91 (and their respective absorption amplitude).

Beneficially, this illustrated profile, as well as a multitude as others, may serve as a “signature” for identifying a gas of interest, not unlike an animal (e.g., drug-sniffing dog) may recognize the smell of certain prohibited items (drugs, explosives, etc.) or even illnesses. Further, while animals are typically trained over a long period and a great expense to detect a single (or few items), a single electromagnetic gas spectrometer may be simply programmed or re-programmed for many different substances of interest.

The inventor has discovered that a by coupling one or more Josephson Junctions (JJs) with an antenna as disclosed herein, the resultant structure may be operative in an electromagnetic gas spectrometer that can scan a wide range of frequencies of interest in the THz range over a short period of time. Further, frequency bands may be tuned or otherwise modified between broader bands (e.g., for search/screening) and narrower bands (e.g., for detection/verification). Further, as discussed below, the electromagnetic gas spectrometer 100 may rapidly scan over an entire THz range to detect a wide variety of substances, even having very complex profiles.

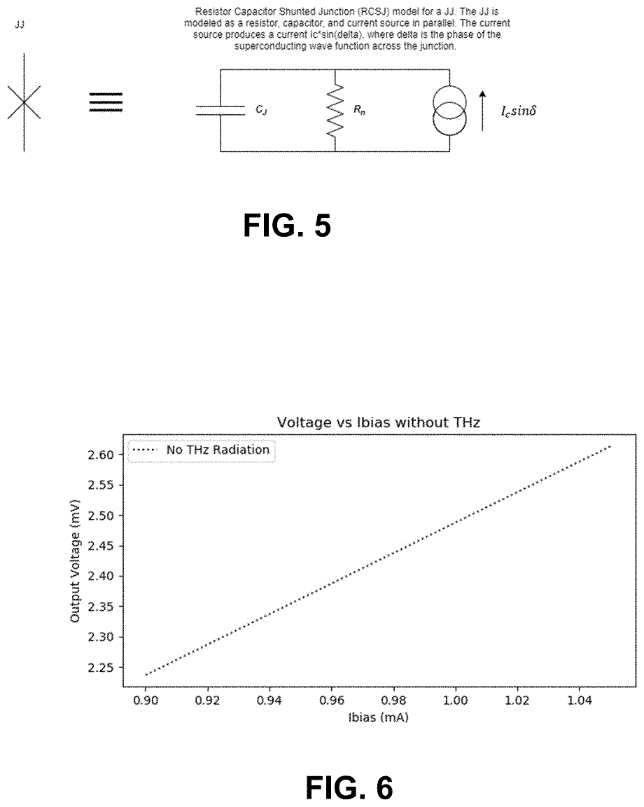

As background, FIG. 5 schematically illustrates a Resistor Capacitor Shunted Junction (RCSJ) model with current noise, for electronically representing a Josephson Junction (JJ) structure. In particular, the JJ, denoted by an ‘x’ intersecting a line, is on the left, and the RCSJ model is on the right. Conceptually, the JJ can be modelled as a resistor, a capacitor, and a current source in parallel. The key parameters of this model are the value of the resistor, called the “normal resistance” and denoted R_N, the junction capacitance, denoted C_J, and the critical current, denoted I_C. The current produced by the current source is I_C sin ?, where ? is the phase of the superconducting wave function across the JJ. These electrical properties describe the behavior of the junction, and they are dependent upon the superconducting material and the junction layout and geometry.

The current produced by the current source in the RCSJ model is superconducting; it represents the super current that is tunneling across the junction and has a maximum value of I_C. If any additional current enters the junction, it is not superconducting current, and must pass through either the resistor or the capacitor. When the non-superconducting current passes through the resistor portion of the JJ, it creates a voltage across the JJ. The phase of the superconducting wave function ? is related to the voltage across the junction according to the equation,

??=??/?t=2e/h V=2?/?_0 V

Where:

e is the elementary charge,

h is Planck's constant,

V is the voltage across the junction, and

?_0 is the elementary unit of magnetic flux, the flux quantum.

This equation shows that when a voltage forms across the junction, the phase of the superconducting wave changes as a function of time. 2e?h equals 483.597 THz per volt, showing that a supercurrent is generated whose frequency is proportional to the voltage: I_C sin ?=I_C sin(2e/h Vt)=I_C sin([483.597 THz?V]Vt) Where t is time in seconds. This relation between voltage and frequency means that when a DC voltage, V, is applied to a JJ it creates a THz current.

Physically, a Josephson Junction (JJ) is a weak link between two superconducting electrodes that blocks direct superconducting current from passing between electrodes but allows superconducting electrons to tunnel from one electrode to the other. There are many ways to form JJs.

One way to form a JJ is by using a focused ion beam to directly write a JJ into a superconducting circuit on a wafer or chip. This method has been shown to work for wires of the high temperature superconductor, Yttrium Barium Copper Oxide (YBCO). The YBCO is grown as a thin crystal layer, less than a few hundred nanometers, on a wafer. It can be etched using photolithographic techniques into circuit patterns, and then a focused ion beam can be used to create JJs in the circuits. The focused ion beam damages the crystal lattice of the YBCO, which destroys the superconductivity in those areas. The ion beam is very narrow, roughly a nanometer in diameter, so it will damage a very narrow area of the superconducting crystal. The area of the crystal that is damaged becomes an insulator. In certain conditions, dependent upon the ion beam spot size, ion energy, and the temperature of the circuit during use, the superconducting electrons can still tunnel across the damaged area formed by the ion beam. Under these conditions, the circuits with the ion damaged areas are JJs.

A second method of forming JJs is to create nanowires between electrodes. YBCO nanowires that function as JJs have been demonstrated where the wires are 200 nanometers long and 60 nanometers wide. They form weak links between the YBCO electrodes and allow superconducting current to tunnel across them.

A third method of forming JJs is to allow a layer of oxide to form in between superconducting metals such as niobium and aluminum. This is done for low temperature superconductors. In this method, photolithographic techniques are used to create microscale wires and circuits, which form a thin oxide layer when exposed to oxygen. Then an additional layer of circuits is created using photolithographic techniques, and where the second layer touches the first layer through the oxide, a JJ is formed. There are many other methods to make JJs, all of which may yield devices that are suitable for the use described in this disclosure.

In a phenomenon called the AC Josephson effect, a 2.067 millivolt DC voltage can be applied to a JJ to create a current that oscillates with a magnitude of I_C and a frequency of 1 THz (this frequency is selected as a convenient reference point). In order to increase the magnitude of the oscillating (AC) current, multiple JJs may be placed in parallel. It has been demonstrated numerous times that JJs in the same circuit with similar values of I_C and R_N will synchronize their oscillations. When a pair of JJs synchronize, they produce current that is coherent, and adds together.

As discussed in greater detail below, an antenna structure may be coupled with a JJ such that THz signals may be emitted or received. In particular, the JJ may be configured to convert voltage to frequency and incorporated as part of an emitter/transmitter. Similarly, the JJ may be configured to convert frequency to voltage and incorporated as part of a receiver.

With regard to emitters/transmitters, the JJ may be configured as a voltage to frequency convertor by maintaining a predetermined DC voltage across the JJ. In particular, it has been shown that a JJ converts voltage to alternating current at a ratio of 2??/?, where ?? is the elementary charge, and ? is Planck's constant. This (2??/?) resolves to 483.597 THz per volt. As applied here, when 2.067 millivolts are applied to a JJ, the JJ will create an alternating current with a frequency of 1 THz. This signal can then be radiated by coupling the JJ to an antenna (e.g., an on-chip antenna).

Alternately, with regard to receivers, the JJ may be configured as a frequency to voltage convertor by applying a DC bias current across the JJ and measuring voltage across the JJ. In particular, it has been shown that a JJ will produce DC voltage steps at an integer multiple (n) of ???/2??, where f is the frequency of an alternating current across the JJ. As applied here, when an alternating current with a frequency of 1 THz is applied across a JJ, the JJ will register a DC voltage that is an integer multiple of 2.067 mV. Further, rather than directly applying the alternating current to the JJ, this alternating current can be received wirelessly by coupling the JJ to an antenna.

FIG. 6 is a plot that shows the voltage output of a Josephson Junction (JJ) for different DC bias currents, and with no alternating currents passing through it. In particular, this is a “baseline” chart of DC voltages registered across a JJ when different DC bias currents are applied over a range of interest, and in the absence of an AC current added. As shown, a DC bias current may be swept through a number of DC values across the JJ (x-axis), and as a result, the DC voltage measured across the JJ (y-axis) will increase linearly. In particular, in the absence of any oscillating currents through the JJ, a bias current will follow Ohm's law, which states that V=IbiasR_N, and which in turn gives Ibias=V/R_N.

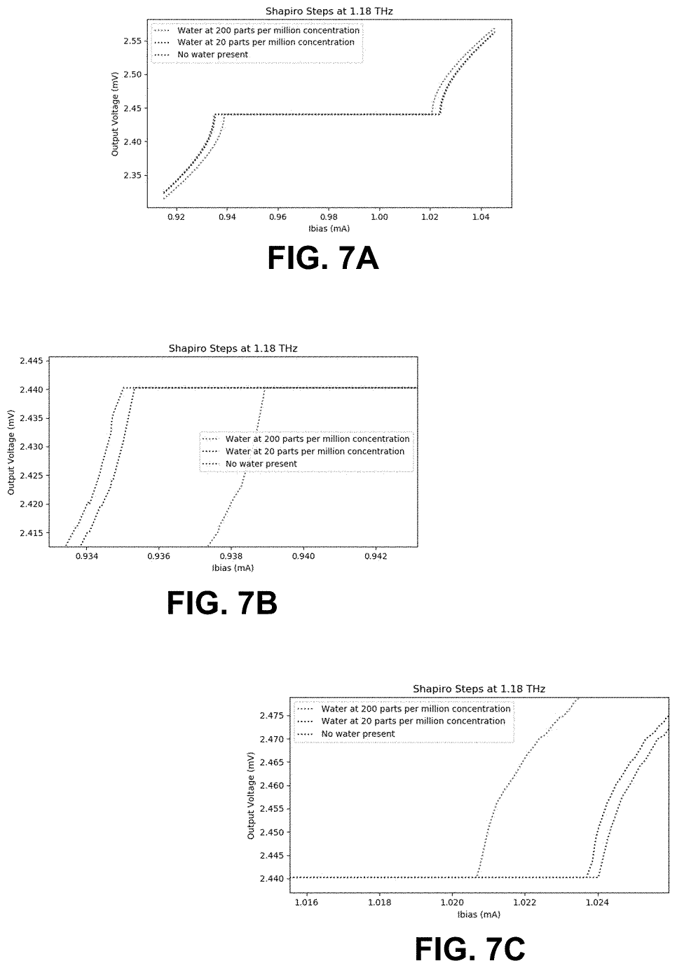

FIG. 7A is a plot that shows the voltage output of a Josephson Junction (JJ) for various DC bias currents over the range of interest, but now with an alternating current passing through it. Further, this chart illustrates another phenomena of JJ's. In particular, when an oscillating current is applied to a JJ, and the DC bias current is swept through a sufficient range of values, the resultant DC voltage across the JJ will have a series of “steps” (i.e., the output voltage departs from a generally linear plot to a “plateaued” plot) that correspond to the alternating current applied to the JJ. Additionally, and as discussed below, the “width” of the step corresponds to the alternating current's power. These voltage steps are called Shapiro Steps.

For reference, each Shapiro Step corresponds to a DC voltage value of: V_step=nfh?2e

Where:

V_step is the voltage of the Shapiro Steps+

n is an integer multiple

f is the frequency of the oscillating current

e is the elementary charge, and

h is Planck's constant.

Accordingly, a 1 THz oscillating current passing through the JJ will produce voltage steps vertically located at integer multiples of 2.067 millivolts. Here, only the first integer step (n=1) is shown, however, a second Shapiro Step would register with a voltage of 4.134 millivolts, albeit with some attenuation present. Further, each successive step will have increased attenuation. As such, only the first Shapiro Step is illustrated, as is of greater interest when applied to the present disclosure.

In addition to having a DC voltage (i.e., vertical location on graph), Shapiro Steps are further defined as having a magnitude or “width”. In particular, when the AC current or signal is also present in the DC bias current, as the DC bias current increases in magnitude, the voltage across the JJ will increase until it reaches a V_step=nfh?2e, and then it will plateau at V_step=nfh?2e as the bias current increases further, and finally it will begin increasing again, until it reaches the next step. In other words, when the DC bias current across the JJ includes a oscillating current component, the DC voltage registered across the JJ will stop increasing at a predetermined value and hold/remain constant across the JJ for some range of DC bias current values. Further, as the magnitude of the oscillating current increases, the “width” of the step increases, meaning that the JJ will have a voltage V_step=nfh?2e for a broader range of values of the bias current.

As applied herein, the bias current of the Terahertz (THz) detector/receiver 130 may be swept across a desired DC bias current range, to search for, locate, and/or confirm any Shapiro Steps 51 and to interpret the frequency or frequencies (i.e., calculate the frequency and its power) received. In particular, a DC bias current may be swept through a number of DC bias current values across the JJ (x-axis), and the resultant DC voltage may be measured across the JJ (y-axis).

For example, here a 1.18 THz alternating current is passed through the JJ, while sweeping the DC bias current between a range of −0.92 mA to −1.04 mA. As a result, and as shown, the 1.18 THz AC current added to the DC bias current produces voltage steps (Shapiro Steps 51) at integer multiples of 2.44 millivolts. It is understood that any frequency(ies) of interest may be searched. Here, the 1.18 THz frequency was conveniently selected for its relationship with water, as discussed further below. Thus, as applied to the present disclosure, by sufficiently sweeping the DC biasing current over a range of interest (e.g., here, from >0.90 mA to <1.04 mA), and measuring the vertical location of the voltage step(s) (e.g., here, first step at 2.44 millivolts), a JJ can be used to determine the frequency of an oscillating current that is passing through it.

In this figure, the Shapiro Step 51 appears as predicted at the same voltage for a gas having no water present 52, a gas with water at 20 ppm present 53, and a gas with water at 200 ppm present 54. However, notably, the greater the concentration of water, the narrower the Shapiro Step 51.

FIG. 7B is a detail view of the left side of the plot of FIG. 7A. FIG. 7C is a detail view of the right side of the plot of FIG. 7A. In particular, each line shows a different beginning and end of the Shapiro Step. As above, the 1.18 THz frequency was conveniently selected for its relationship with water. Further, as more readily visible here in detail, each line represents a different amount of water present. In particular, while the general Shapiro Step 51 appears at the same voltage for each gas, the curve for the gas having no water present 52 has a wider step than curve for the gas with water at 20 ppm present 53, which then has a wider step than the gas with water at 200 ppm present 54. Thus, the greater the concentration of water, the narrower the Shapiro Step 51. The reason for this is that water absorbs some of the 1.18 THz energy passed through it.

As such, the “width” of the Shapiro Step is proportional to the magnitude of the oscillating current that is received (e.g., via the THz detector/receiver 130) or added to (e.g., via the THz emitter/transmitter 120) the bias current. Beneficially to the present disclosure, a series of measurements of the width of the step can be used to determine the magnitude of the oscillating current that is passing through the JJ. For example, here with respect to water, the 1.18 THz signal may be first be emitted through a gas to determine a baseline width, and from there emitted through a first and second gas sample with unknown amounts of water present, and by measuring the reduction in with of the Shapiro Step 51, the amount of water present may be calculated.

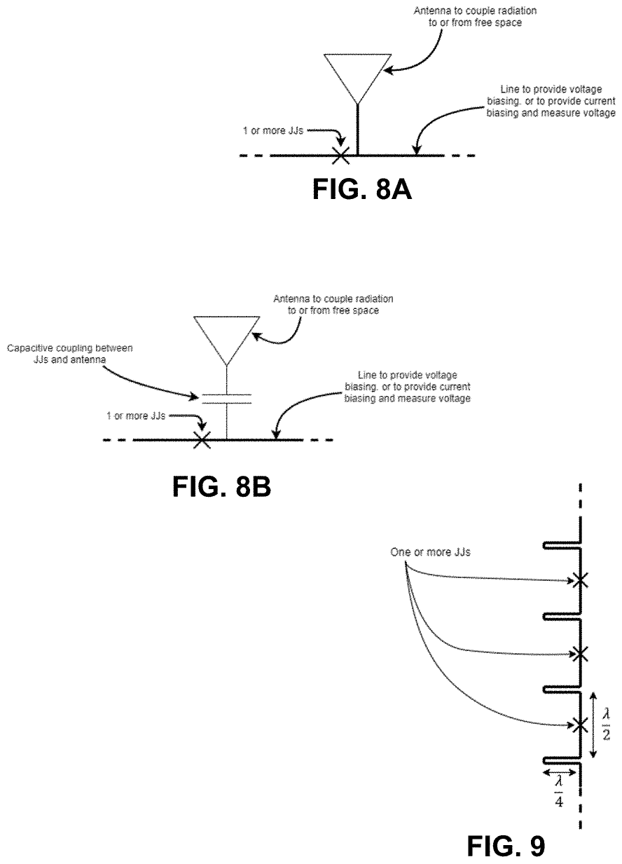

FIG. 8A is a schematic diagram of an exemplary THz detector/receiver (or THz emitter/transmitter), according to one embodiment of the disclosure. In particular, in order to detect electromagnetic radiation, the Josephson Junction (JJ) should be coupled to an antenna structure. FIG. 8B is a schematic diagram of an exemplary THz detector/receiver (or THz emitter/transmitter), according to another embodiment of the disclosure. In particular, in order to detect electromagnetic radiation, the Josephson Junction (JJ) may be electromagnetically coupled to the antenna structure, as opposed to directly coupled.

As shown, a generic emitter/detector 110 may include an antenna structure 112 and at least one Josephson Junction (JJ) 114 Structurally, the JJ 114 may be electrically coupled directly to the antenna 112. Also or alternately, the JJ 114 may be electromagnetically coupled indirectly to the antenna 112 (e.g., inductively, capacitively, etc.). Additionally, the order of coupling of the JJ 114 and the antenna 112 may be agnostic to a polarity of DC current across the JJ 114. It is understood that these schematic diagrams are symbolic and in no way limited to one particular antenna. It is further understood that the generic emitter/detector 110 may be arranged as the THz emitter/transmitter 120 and/or the THz detector/receiver 130, for example, depending on whether an oscillating current is being transmitted or received via the antenna 112.

The antenna structure 112 may be configured to couple radiation to or from free space. According to one embodiment, the antenna 112 may preferably be made of a high temperature superconductor. For reference, when the electromagnetic wave is incident upon the antenna 112, the antenna will develop a current that is oscillating at the frequency of the electromagnetic wave. Of particular interest here are THz waves, both for reception and emission.

The JJ 114 may be directly embedded in the antenna 112, or it may be electromagnetically coupled to the antenna so that oscillating currents in the antenna also appear in the JJ 114. Further, the JJ 114 may be electrically coupled to a line to provide voltage biasing, and/or to provide current biasing and measured voltage. While, for clarity, one JJ 114 shown, it is understood that a plurality of JJs 114 may be used. Further, the JJs 114 may be arranged in parallel and/or series, as discussed herein.

As above, the emitter/detector 110 may be used for emission or reception. In particular, in order to radiate and/or receive effectively, the JJ 114 should be properly coupled to the antenna structure 112. When the emitter/detector 110 is functioning as an emitter, the JJ 114 may radiate its signal into free space or over-the-air. This may be done by efficiently coupling the JJ 114 with the antenna structure 112. When the emitter/detector 110 is functioning a detector, the antenna structure 112 may be used to communicate signals received from free space to the JJs 114. Again, this may be done via efficiently coupling the antenna structure 112 to the JJ 114.

Further, when the emitter/detector 110 is functioning as an emitter, the antenna 112 may be coupled to the JJ 114 with sufficient proximity to induce the sinusoidal alternating current that arises from the AC Josephson effect on the antenna 112. In particular, when the structure is functioning as a detector, the antenna may be coupled to the JJ with sufficient proximity that an alternating current that is induced in the antenna by an incident electromagnetic wave is also induced across the JJ. For example, the JJ and the antenna may be separated by 3 millimeters or less. Also for example, the JJ and the antenna may be separated by a distance related to the frequency, frequencies, or frequency range of interest (e.g., at 1 THz, a millimeter is a little over 3 wavelengths). Also for example, and similarly, the JJ and the antenna may be separated by a fraction of the wavelength, wavelengths, or wavelength range of interest (e.g., ¼ wavelength, ½ wavelength, etc.). Also for example, the JJ and the antenna may be separated by a significantly greater distance where coupled together with a waveguide. Also for example, the JJ may be integrated with or otherwise collocated on the antenna (e.g., Franklin antenna).

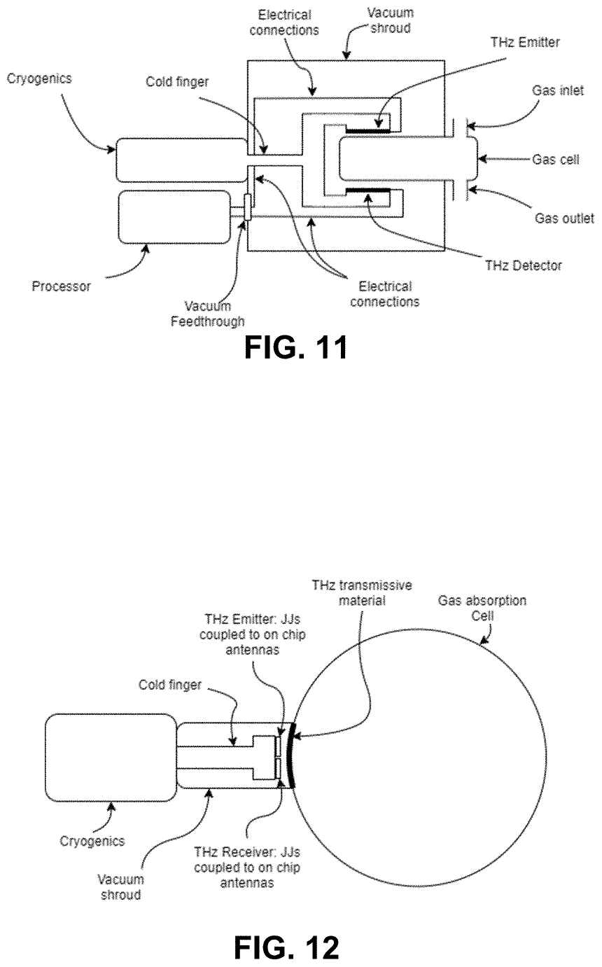

In operation, the emitter/detector 110 may be operated by a controller 190 (FIG. 11). In particular, when the emitter/detector 110 is functioning as an emitter, the JJ 114 may be driven by a constant voltage provided by control electronics in the controller 190 (FIG. 11). When the emitter/detector 110 is functioning as a detector, JJ 114 may create a constant voltage that must be electronically measured. In both cases, the JJ 114 may be directly and/or indirectly coupled to the control electronics in the controller 190. It is understood, the controller 190 may be any conventional controller including processing and electronics appropriate for operating the emitter/detector 110. Further, the controller 190 may be configured to operate one or more other subsystems of the electromagnetic gas spectrometer 100.

As above, a plurality of JJs 114, may be electronically coupled to the antenna structure 114 in series and/or in parallel, as needed. For example, when the emitter/detector 110 is functioning as a detector, multiple JJs 114 may be coupled in series to increase the output voltage as desired. In particular, the voltage from each JJ 114 will add linearly. In contrast, while the noise produced by each JJ 114 will also add, but it will do so incoherently, and so the noise will only increase with the square root of the number of JJs 114. This technique can be used to increase the measured signal to noise ratio and to provide more accurate and precise estimates of the frequency and magnitude of the oscillating current that is passing through the JJs. Also for example, placing JJs 114 in parallel will decrease the output noise of the JJ 114 and maintain the same voltage, which will also increase the signal to noise ratio.

In general, in order to transfer power most efficiently between the JJs 114 and other structures such as the antenna 112, the JJs 114 should be made to have the same impedance as the other structures. To change the aggregate resistance of the JJs 114, the JJs 114 may be placed in series or in parallel. The aggregate resistance of the JJs 114 can be increased by adding more JJs 114 in series. Alternately, the aggregate resistance of the JJs 114 can be decreased by placing them in parallel.

Further, the antenna 112 will have a radiation resistance that is a function of its geometry and the frequency of the signal of interest. The higher the radiation resistance of the antenna 112, the more effective the antenna 112 will be at radiating power. The power that is radiated is proportional to the current squared multiplied by the radiation resistance of the antenna 112. To transfer power efficiently from the JJs 114 into free space, the aggregate resistance of the JJs 114 should be optimally matched to be same as the radiation resistance of the antenna 114. The aggregate resistance of the JJs 114 can be increased by placing more JJs 114 in series. The aggregate resistance of the JJs 114 can be decreased by placing them in parallel.

According to one embodiment, the antenna structure 112 may be configured as a Franklin Antenna (see e.g., FIG. 9). A Franklin antenna solves the problem of having a source that needs to be DC coupled to control electronics but also needs to be able to efficiently couple energy to and from free space. In a Franklin antenna, one or more of the collinear half wavelength segments would contain one or more JJs, fabricated in the center of the segment.

FIG. 9 is a schematic diagram of an exemplary THz detector/receiver (or THz emitter/transmitter), according to one embodiment of the disclosure. In particular, a Franklin antenna is schematically shown here as the antenna structure 112. As above, one or more Josephson Junctions (JJs) 114, may be electronically coupled to the antenna 112.

As illustrated, and as above, according to a preferred embodiment, a Franklin antenna may be used to either transmit or receive in conjunction with the JJ(s). A Franklin antenna is composed of an array of collinear half wavelength segments, where each segment is connected by an orthogonal stub whose total length is a half wavelength. The Franklin antenna is well suited for this because it can be connected to a biasing current or voltage.

As discussed earlier, the biasing current or voltage is used to readout frequencies or to generate frequencies, respectively, and is a crucial part of the system. The Franklin antenna may be fabricated from superconducting materials on the same chip as the JJs 114. According to one embodiment, these may include high temperature superconducting materials, Further, the JJs 114 may be embedded in the center of one or more of the collinear half wavelength segments.

According to another embodiment, an antenna 112 may be a log periodic antenna. This may be used for either the transmit or the receive variation. A log periodic antenna consists of more than one half-wave dipole segments of increasing length. The segments are fabricated on the same chip as the JJs out of superconducting material. The JJs 114 may be directly connected to them, or they may be electromagnetically coupled to the antenna 112.

It is contemplated that other antenna structures 112 may be used as well. According to one embodiment, many antennas could in fact be used, for example, by capacitively coupling them with the circuit containing the JJs 114. Capacitively coupling the antennas to the circuit containing the JJs allows the AC signal to pass between the JJs 114 and the antenna structure 112 but does not allow the DC signal to pass between the two. An example of another antenna structure that could be used is a Yagi-Uda antenna. Another example of an antenna structure that could be used is a dipole antenna. Another example of an antenna structure that could be used is a patch antenna.

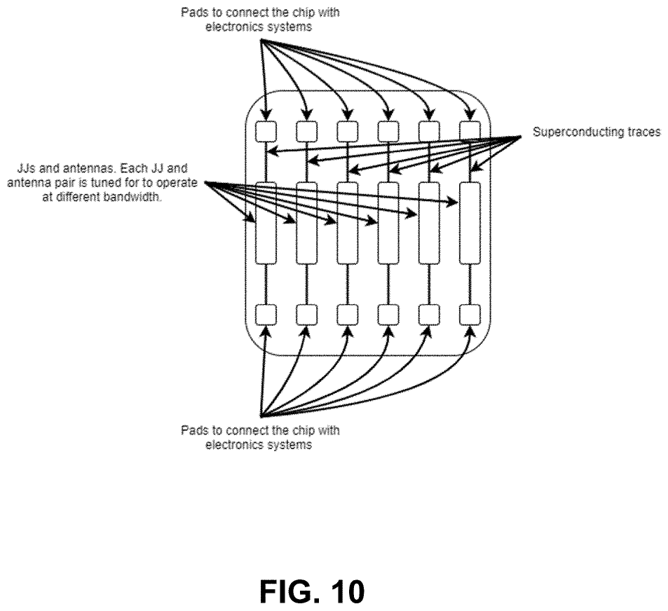

FIG. 10 is a schematic diagram of an exemplary THz detector/receiver (or THz emitter/transmitter), according to one embodiment of the disclosure. In particular, here multiple Josephson Junction (JJ) 114 and antenna pairs 112 may be included. As above, an antenna's geometry affects how efficiently it can radiate or receive electromagnetic energy. An antenna radiates or receives some wavelengths of electromagnetic energy more efficiently than other wavelengths of electromagnetic energy. In order to be able to radiate or receive a broad bandwidth, multiple antennas may be used.

According to one embodiment, each of these antennas may be fabricated on the same chip as the JJs, and each antenna may be of the same general type, such as a Franklin antenna or a log periodic antenna, but will have different sizes so that they can radiate or receive different bandwidths efficiently. Each antenna may be coupled with the same JJ or group of JJs, or each antenna may be coupled with a different JJ or group of JJs.

For example, the antenna structure that is used may have some bandwidth about which it can efficiently couple energy to and from free space. However, it may not be able to efficiently couple energy to and from free space for frequencies outside of this bandwidth. In order to have a larger total bandwidth, the disclosure may use multiple antenna structures, each of which has a different bandwidth. Advantageously, multiple antennas can also be used to generate more power, or to detect signals with better signal to noise ratios.

According to one embodiment, the disclosure may use an antenna structure 112 that efficiently couples energy to and from free space at a bandwidth between 1 THz and 1.3 THz, and may use a second antenna structure that couples energy to and from space at a bandwidth between 1.3 THz and 1.6 THz. In this way the disclosure is able to efficiently generate and detect frequencies across an extended bandwidth.

According to one embodiment, multiple antennas 112 may be fit on a single chip (because the wavelengths at these frequencies are small). In particular, the antennas can be formed on the same chip as the JJs 114 out of the same superconducting material that is used to form the JJs 114. As shown and as above, multiple JJs and antennas may be included together, where each JJ 114 and antenna 112 pair is tuned to operate at a different bandwidth or range of interest. For example, the multiple JJs 114 and antennas 112 may be selected and configured to operate together over a range of 1 THz and 1.6 THz, with individual pairs covering sections thereof. Further, the multiple JJs 114 and antennas 112 may be formed together or otherwise mounted together, where each individual JJ 114 and antenna 112 pair includes superconducting traces extending therefrom to pads (or other interfaces) to connect the unit (e.g., chip) with electronics and controls of the controller 190. As above, these superconducting traces may be made of high temperature superconducting materials.

At atmospheric pressure, a molecule's resonant peaks in the THz frequency band are a few gigahertz wide. The THz emitter 120 can generate tones that cover the entire frequency band, where each tone is spaced by some frequency from the other tones. One example frequency spacing for sequential tones is one gigahertz. Alternatively, a series of tones can be generated where each tone is placed on one or more resonant absorption peaks of a specific molecule. This is done to detect the presence of that molecule. The device can be made to look for the presence of multiple molecules; this is done by causing the emitter to generate tones at one or more of the resonant absorption peaks of each molecule.

In order to improve the signal to noise ratio, the THz emitter 120 and the THz detector 130 may be configured to function as a lock-in amplifier. In this configuration, the emitter may be turned on and off at some lock in modulation frequency, f_(lock-in). For a JJ THz emitter, the output is turned on and off at the modulation frequency by turning on and off the DC voltage, V, at that modulation frequency f_(lock-in). f_(lock-in) might be 1 kilohertz, 10 kilohertz, or 100 kilohertz, or it could be other frequency values.

Multiple tones can be generated concurrently, where each tone can be generated by a different THz emitter 120.

Voltage measurements: V_samples may be made across the JJs 114 that are configured to detect the received radiation. Recalling that a bias current in the THz detector 130 may be applied to the JJs 114, the JJs 114 may be swept through values that are designed to sense the presence of voltage steps at V_step=nfh?2e. The width of the step is proportional to the power of the received signal. Here, “width” is defined as the amount of current that above and below I_Bias=V_step?R_N that still produces a voltage V_step (i.e., the difference between the current when the step ends and the step begins).

In this way, when no signal is received, the step will have no width; when a relatively small amount of power in the tone is received, the voltage V_step will only be measured for a relatively small range of values of I_Bias above and below V_step?R_N. As the received power in the tone increases, the range of values of I_Bias that produce V_step?R_N will increase. Thus, by sweeping the bias current and measuring the voltage, the width of the steps can be measured and the power in a received tone can be estimated.

When configured in a lock-in configuration, it is advantageous to modulate the bias current with the same modulation frequency f_(lock-in) as is used with the THz emitter.

Alternatively, the measured voltage samples V_samples can be multiplied digitally by a modulation signal S_(lock-in) at the modulation frequency f_(lock-in) after they have been sampled. The measured voltage samples V_samples may be copied, and the copy of V_samples can be multiplied with a second copy of the S_(lock-in), offset from the first copy of S_(lock-in) by 90 degrees. The version of V_samples that is multiplied by the first copy of S_(lock-in) is called the in-phase output; the version of V_samples that is multiplied by the second copy of S_(lock-in), which is offset by 90 degrees from the first copy of S_(lock-in), is called the quadrature output. Computing the magnitude of the vector formed by the in-phase and quadrature output removes the dependency of the output on the phase of the modulation signal S_(lock-in).

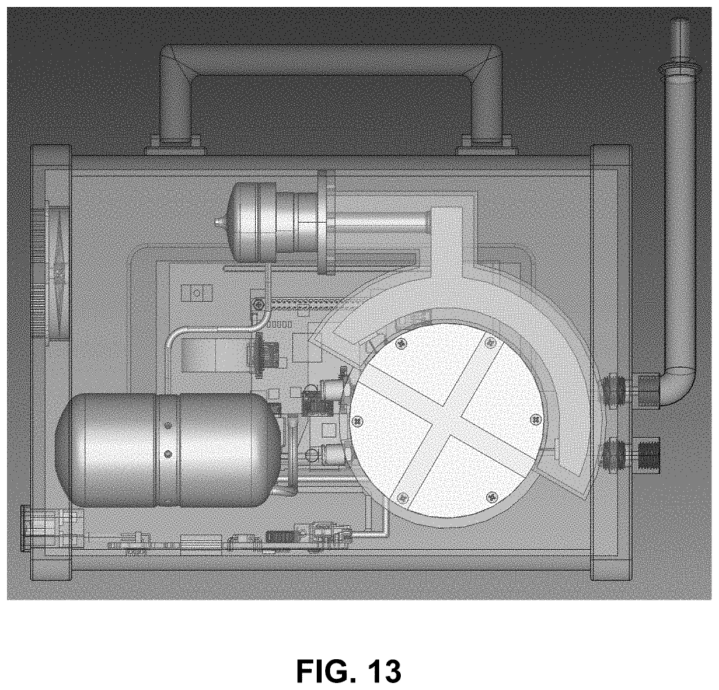

FIG. 11 is a schematic diagram (radial view, relative to the gas absorption cell) of an exemplary electromagnetic gas spectrometer, according to one embodiment of the disclosure. FIG. 12 a schematic diagram (axial view, relative to the gas absorption cell) of a detail of the exemplary electromagnetic gas spectrometer of FIG. 11, according to one embodiment of the disclosure. In particular, the electromagnetic gas spectrometer may be configured to generate and detect THz frequencies via one or more Josephson Junctions (JJs) electronically to antenna structures. As illustrated, the electromagnetic gas spectrometer may generally include a gas absorption cell having a gas inlet and a gas outlet, a THz Emitter, a THz Detector, a cryogenics system configured to chill superconducting components of the THz Emitter and Detector, a vacuum structure configured to insulate the superconducting components of the THz Emitter and Detector, and a controller.

As above, JJs are electrical structures that, inter alia, convert from a constant voltage to an alternating current (AC) and vice versa. JJs are formed when a weak link is placed between superconducting electrodes, allowing the superconducting Cooper pairs to tunnel across the junction. Further, the JJs are formed in superconductors, which function at cryogenic temperatures. Thus, the electromagnetic gas spectrometer may include a means to cool the JJs to cryogenic temperatures. One example of a means to cool the JJs is by mounting them on a thermally conductive structure called a cold finger. The cold finger is cooled by attaching it to a cold source such as a cryogenic cooler or liquid nitrogen. Examples of cryogenic coolers include Stirling engines, Joule-Thompson coolers, and others.

The chips containing the JJs may be surrounded by vacuum structure such as a vacuum shroud. The JJs may be maintained in a vacuum by the vacuum shroud. In particular, the vacuum shroud maintains vacuum on the inside and atmospheric on the outside. According to one embodiment, the vacuum shroud can be constructed from a material that allows the electromagnetic radiation to pass through it. Alternatively, the vacuum shroud can be made from a material that is not transparent to the electromagnetic radiation, but it may have windows in it that allow the radiation to pass through it. Teflon is one example of a vacuum shroud material that allows the electromagnetic radiation to pass through it. An example of a vacuum shroud material that does not allow the electromagnetic radiation to pass through it is aluminum.

Once the radiation leaves the vacuum shroud, it enters a gas absorption cell that is full of the gas that it is analyzing. The gas absorption cell must allow the radiation to enter and leave it. This could be done using windows made of material that allows the radiation to pass through it. The gas absorption cell must have ports that allow the gas to enter it and leave it. The ports may be connected to gas tubes that allow the gas to flow through it. The gas tubes may have valves that allow gas to flow in only one direction, or that stop the flow of gas entirely. The gas tubes may have connectors to allow them to be connected to other gas tubes. The gas tube that allows gas to flow into the gas absorption cell may have an attachment on its end that allows a person to blow on it (similar to a breathalyzer mouthpiece). The gas tube that allows gas to flow out of the gas absorption cell may have a filter on it.

FIG. 13 is a cutaway back view of an exemplary implementation of an electromagnetic gas spectrometer, according to one embodiment of the disclosure. Here the electromagnetic gas spectrometer 100 is configured as a portable test unit. In particular, the electromagnetic gas spectrometer 100 may be incased in a housing 102 such as a suitcase. As above, the electromagnetic gas spectrometer 100 may include a THz emitter 120, a THz detector 130, a cryogenics system 150, a vacuum structure 160, a gas absorption cell 170, and a controller 190.

Further, the electromagnetic gas spectrometer 100 may include at least one user interface 180. For example, here the electromagnetic gas spectrometer 100 is configured to detect substances in a user's breath (e.g., alcohol, virus, gas of interest, etc.). As such, the user interface 180 may include a breathalyzer attachment 182 that is configured to allow a user to blow into it and communicate the user's breath sample into the gas absorption cell 170 for testing.

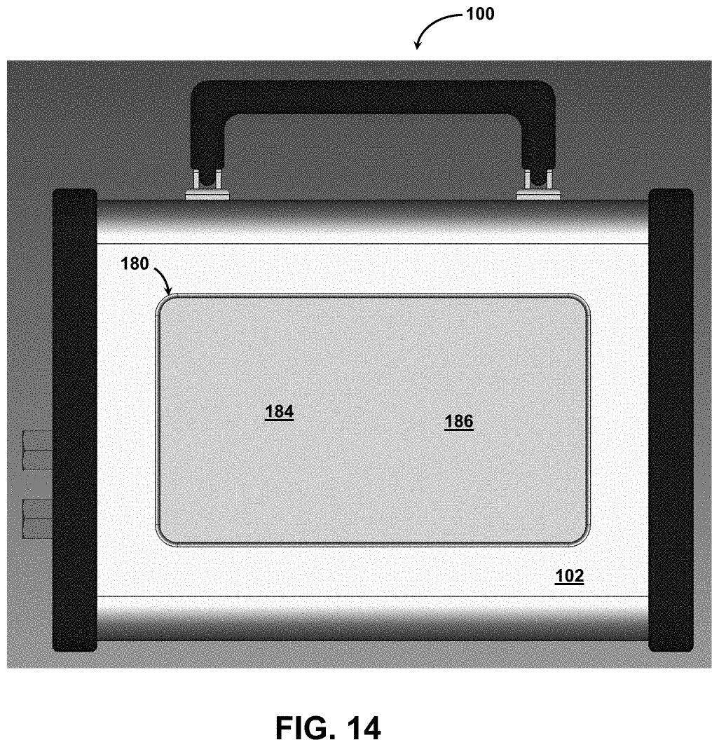

FIG. 14 is a front view of the electromagnetic gas spectrometer of FIG. 13, according to one embodiment of the disclosure. As above, the electromagnetic gas spectrometer 100 may be incased in a housing 102 such as a suitcase. According to one embodiment the user interface 180 may include a display 184 and/or a data entry device 186. For example, the display 184 and the data entry device 186 may be integrated into the housing 102. In this way, the housing 102 of the electromagnetic gas spectrometer 100 may be shielded and/or sealed within the housing 102 when the electromagnetic gas spectrometer 100 is operated. Preferably, the display 184 and the data entry device 186 may be combined together, for example as a touch pad.

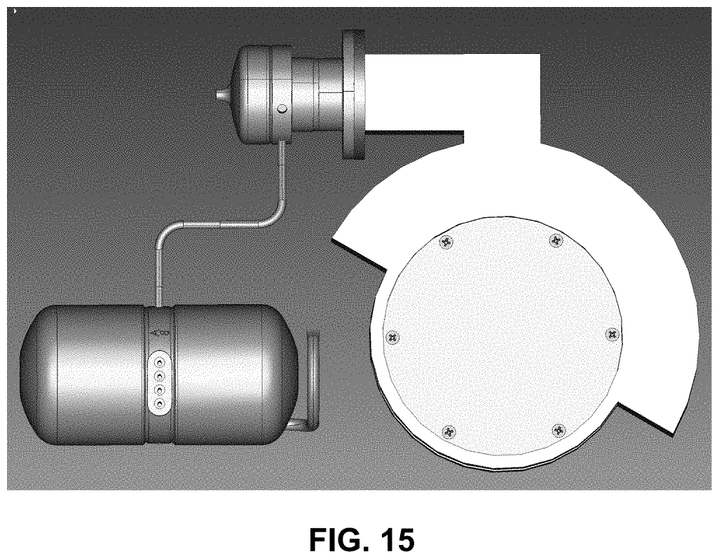

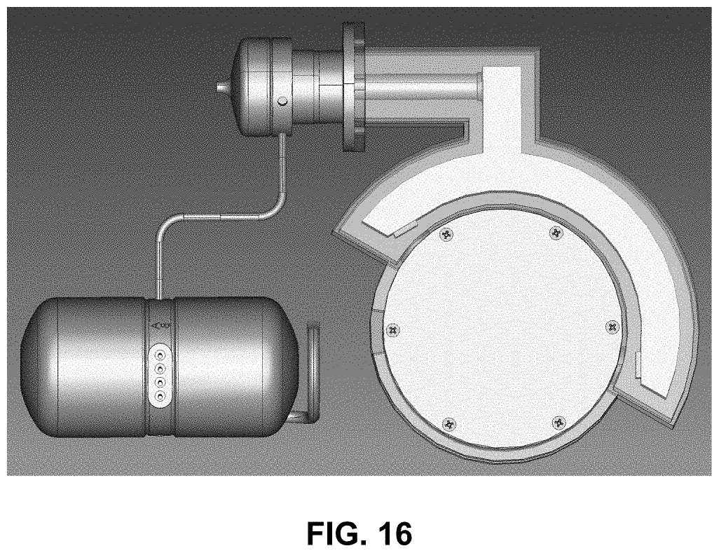

FIG. 15 is a detail back view of the electromagnetic gas spectrometer of FIG. 13, according to one embodiment of the disclosure. FIG. 16 is a detail cutaway back view of the electromagnetic gas spectrometer of FIG. 13, according to one embodiment of the disclosure. As above, the electromagnetic gas spectrometer 100 may include the THz emitter 120, a THz detector 130, the cryogenics system 150, the vacuum structure 160, and the gas absorption cell 170.

Also as above, the THz emitter 120 and/or the THz detector 130 may preferably be configured to generate and detect THz frequencies via one or more Josephson Junctions (JJs) electronically coupled to antenna structures. Further, the THz emitter 120 and/or the THz detector 130 may preferably include multiple JJ and antenna pairs, where each JJ and antenna pair is tuned to operate at a different bandwidth or range of interest.

The JJ emitter and detector must be cooled below their transition temperature so that they become superconducting. A cryocooler or cryogen cooling system is used to cool a cold finger 152 down. The superconducting electronics (e.g., THz emitter 120 a and THz detector 130) are mounted on the cold finger 152. The cold finger 152 may be made from a thermally conductive material such as copper or aluminum.

The cooling is done under a vacuum. The vacuum is separated from the atmosphere by the vacuum structure 160. The vacuum structure 160 may include a vacuum shroud 162. The THz radiation must travel through the vacuum shroud 162 to interact with the gas that is being analyzed. Portions of the vacuum shroud 162 may be made from a material that blocks THz radiation, but that contains windows made from material that allows THz radiation to pass. THz radiation passes through some plastics and crystals. One plastic that allows THz radiation to pass is Polytetrafluoroethylene (PTFE), also called Teflon. Another plastic that allows THz radiation to pass is Polymethylpentene (PMP), also called TPX. Crystals that allow THz radiation to pass include quartz and sapphire. Aluminum is a preferred material that may be used for the portions of the vacuum shroud that block THz transmissions.

After the THz radiation passes through the vacuum shroud 162, it must interact with the gas that is being analyzed. This is done in a gas absorption cell 170. The gas absorption cell 170 is configured so that the THz radiation enters the gas absorption cell 170 from the vacuum shroud 162, passes through the gas, and then exits the gas absorption cell 170, back into the vacuum shroud 162, and shines on the THz detector THz detector 130. The window or transmissive portion of the vacuum structure 160 presses directly against the gas absorption cell 170 to allow the THz radiation to enter and exit the gas absorption cell 170. An O-ring or a gasket can be used to seal the gas absorption cell 170 where the vacuum structure 160 presses against it.

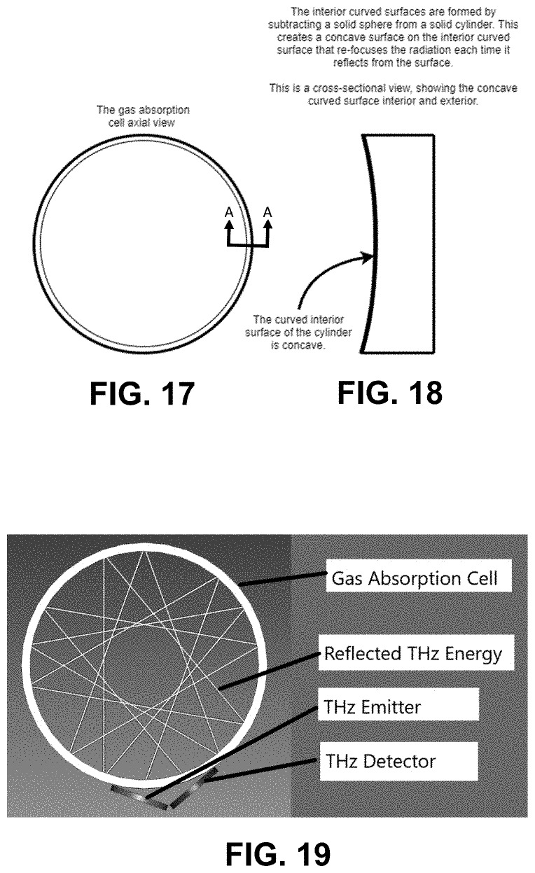

FIG. 17 is a detail section view (axial view) of a gas absorption cell for the electromagnetic gas spectrometer of FIG. 13, according to one embodiment of the disclosure. In particular, the gas absorption cell 170 may be arranged so that the radiation will reflect one or more times before it leaves the gas absorption cell 170. This is done to increase the path length that the radiation takes through the gas while minimizing the overall size of the gas absorption cell 170 (and the electromagnetic gas spectrometer 100 in general).

Each reflection may occur on a surface that focuses the radiation. This is done so that the radiation remains in a tight beam. One example of a gas absorption cell the gas absorption cell 170 is cylindrical in shape, where the radiation will bounce multiple times around the edges of the cylinder. The edges of the cylinder may be concave, so that at each reflection the beam is focused.

FIG. 18 is a cross-sectional view of the gas absorption cell for the electromagnetic gas spectrometer of FIG. 17, along line A-A, according to one embodiment of the disclosure. As shown, the gas absorption cell 170 may be arranged so that the radiation re-focuses itself as it bounces around the edges of the cylinder wall. In particular, and as above, the interior surface may have a spherical curvature that refocuses the radiation each time it reflects from the surface. An example may be found in N. Rothbart et al., “A Compact Circular Multipass Cell for Millimeter-Wave/Terahertz Gas Spectroscopy,” IEEE TRANSACTIONS ON TERAHERTZ SCIENCE AND TECHNOLOGY, VOL. 10, NO. 1, pp. 9-14, JANUARY 2020, the contents of which are incorporated herein by reference in their entirety.

FIG. 19 is a schematic representation of a THz transmission making multiple passes in the gas absorption cell of FIG. 13, according to one embodiment of the disclosure. As above, and as illustrated, the radiation may reflect multiple times from the interior of the gas absorption cell 170 before exiting the gas absorption cell 170 and shining on the THz detector 130. This is done to increase the path length of the THz radiation where it can interact with the gas, while keeping the overall size of the gas absorption cell 170 small.

Keeping the gas absorption cell small is desirable because it allows smaller samples of gas to be analyzed, and it allows the device to be made portable. Increasing the path length increases the amount of energy that is absorbed by the gas. In particular, Beer's Law states that A=εlc, where A is the absorbance that should be maximized, ε is the absorptivity of the attenuating species of gas, l is the optical path length, and c is the concentration of the attenuating species of gas. Reflecting multiple times from the interior of the gas absorption cell 170 before exiting the gas absorption cell 170 increases l, the optical path length, and thus increases the absorbance A.

As above, the reflective surfaces may be shaped to re-focus the THz radiation. This is done to keep the THz beam from spreading out too much before it hits the THz detector 130; if it spreads out too much, some of the beam will not be incident on the THz detector 130, and that portion of the beam will be wasted. If the reflective surfaces are made from a concave shape, they can be used to re-focus the beam.

In order to reflect the THz radiation efficiently, the reflective surfaces of the gas absorption cell 170 should be highly polished, with surface roughness much less than the wavelength of the THz radiation. 10 THz radiation has a wavelength of roughly 30 microns. The surface roughness of the reflective surfaces should less than one micron.

According to one embodiment, the reflective surfaces may be fabricated from a base material, and then coated with one or more materials that can be highly polished, resist corrosion, and/or are scratch resistant. One example of a base material is aluminum. A second example of a base material is copper. An example of a secondary material is gold. Another example of a secondary material is silicon monoxide.

According to one embodiment, the outer shape of the gas absorption cell 170 is cylindrical. The interior surface of the curved portion of the cylinder interior form the reflective surfaces of the cylinder. In order to re-focus the beam, these interior reflective surfaces are formed by subtracting a spherical solid from a solid cylinder. The spherical solid's center is at the center of the cylinder. The radius of the spherical solid may be less than the radius of the cylinder. The cylinder “caps” (or top and the bottom of the cylinder) are removed for clarity, but are generally not made by subtracting a spherical solid from a solid cylinder. Instead, they may be made of flat circular pieces of material that are adjoined to the curved portion using screws and sealed with a gasket or O-ring.

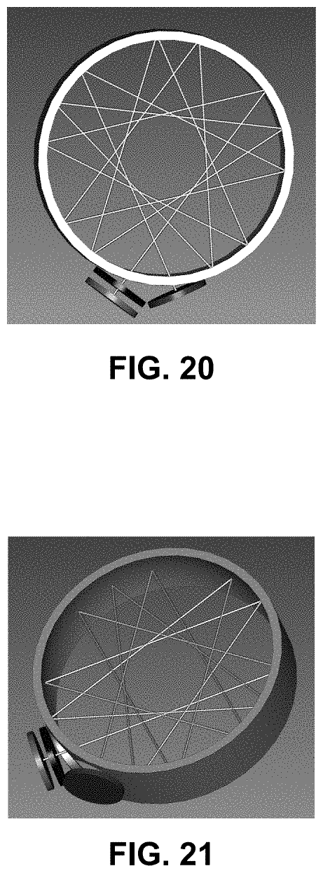

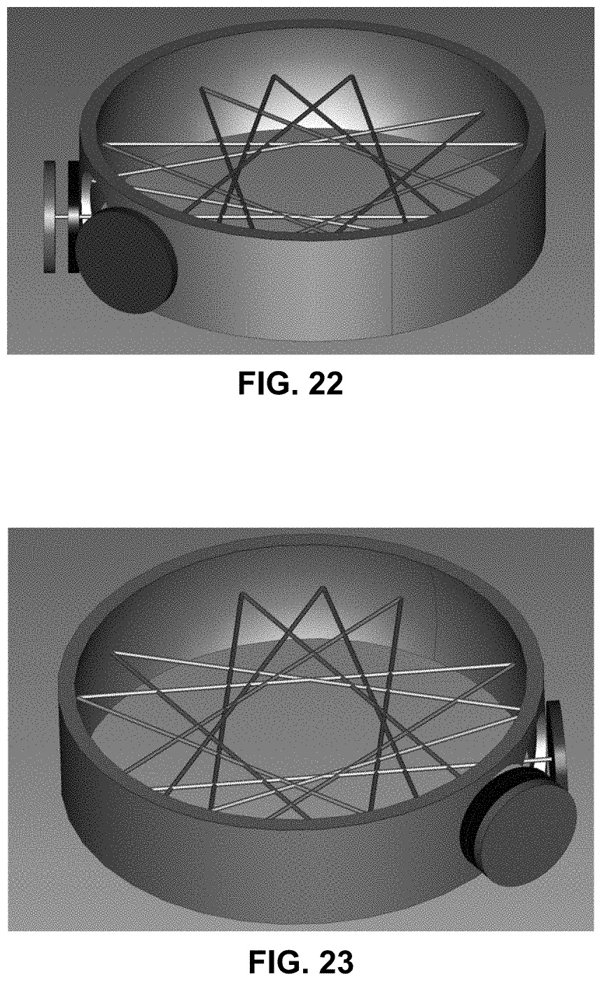

FIG. 20 is a schematic representation (axial view) of a THz transmission making multiple passes in the gas absorption cell of FIG. 13, according to one embodiment of the disclosure. This view shows the emitter, the detector, and a focusing lens outside of the gas absorption cell. FIG. 21 is a schematic representation (perspective view) of a THz transmission making multiple passes in the gas absorption cell of FIG. 13, according to one embodiment of the disclosure. This view shows the emitter, the detector, and a focusing lens outside of the gas absorption cell. FIG. 22 is a schematic representation (alternate perspective view) of a THz transmission making multiple passes in the gas absorption cell of FIG. 13, according to one embodiment of the disclosure. This view shows the emitter, the detector, and a focusing lens outside of the gas absorption cell. FIG. 23 is a schematic representation (alternate perspective view) of a THz transmission making multiple passes in the gas absorption cell of FIG. 13, according to one embodiment of the disclosure. This view shows the emitter, the detector, and a focusing lens outside of the gas absorption cell. As above, the radiation may reflect multiple times from the interior of the gas absorption cell 170 before exiting the gas absorption cell 170 and shining on the THz detector 130.

As shown, the gas absorption cell 170 may be include radiation entry port and a radiation exit port. According to one embodiment, one or both of the radiation entry port and a radiation exit port may be defined by a physical opening through the wall of the gas absorption cell 170. In this embodiment, the vacuum shroud may seal the gas absorption cell 170 or otherwise be configured to prevent any escape of the gas to be analyzed.

Alternately, one or both of the radiation entry port and a radiation exit port may be defined by an electromagnetic radiation opening through the wall of the gas absorption cell 170. In particular, the electromagnetic radiation opening may be defined as a discontinuity in the wall of the gas absorption cell 170 from a material that does not allow the electromagnetic radiation to pass through it (e.g., the base material and secondary material described above) to any appropriate material that does allow the electromagnetic radiation to pass through it. As with the vacuum shroud above, Teflon is one example of a material that allows the electromagnetic radiation to pass through it.

According to one embodiment, the THz emitter 120 may include one or more focusing lenses 112. The focusing lens may be configured to focus the THz transmission. The focusing lens is similar to focusing lenses used in visible or infrared optics, except that it may be made of a material that will not attenuate the terahertz radiation. When radiation is generated by the emitter, it will radiate in a pattern that is a function of the geometry of the antenna. As it passes through the lens, it will be focused so that more energy will enter the gas absorption cell, and travel in the desired path. The focal length of the lens should be chosen so that the maximum amount of energy is directed along the desired path. Each lens may be a single convex lens or a double convex lens, or a different type of lens. A commonly used material for terahertz lenses is TPX, or Polymethylpentene. Another commonly used material is PTFE, or Teflon. The lens may also be placed in front of the detector, to focus energy from the cell onto the detector.

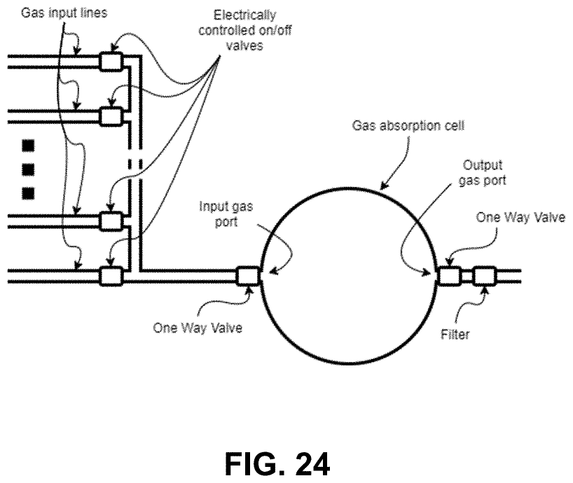

FIG. 24 is a schematic diagram of the gas absorption cell of FIG. 13, along with associated plumbing, according to one embodiment of the disclosure. The gas absorption cell may be connected to some systems to control the source or flow of the gas that enters the cell. In one example, a one-way valve may be attached to the inlet of the cell, to prevent gas from flowing from the cell out the inlet. In another example, one or more electrically controlled valves can be used to allow the user to select the source of the gas that is being analyzed.

A source of inert gas, such as nitrogen, may be used to flush out the cell in between samples. An electrically controlled valve can be used to select the inert gas as the source of gas for analysis. A filter may be placed on the output inlet of the gas absorption cell. This can prevent undesirable gas contents from being emitted by the gas absorption cell. A one-way valve may be attached to the outlet of the cell, to prevent gas from flowing into the cell from the outlet.

The THz spectroscope may be placed at the output of a gas chromatography (GC) system. Since the THz spectroscope tests gasses non-destructively, it can be placed after the GC system, but before the other sensors that are commonly used with GC systems, such as mass spectrometers and flame ionization detectors.

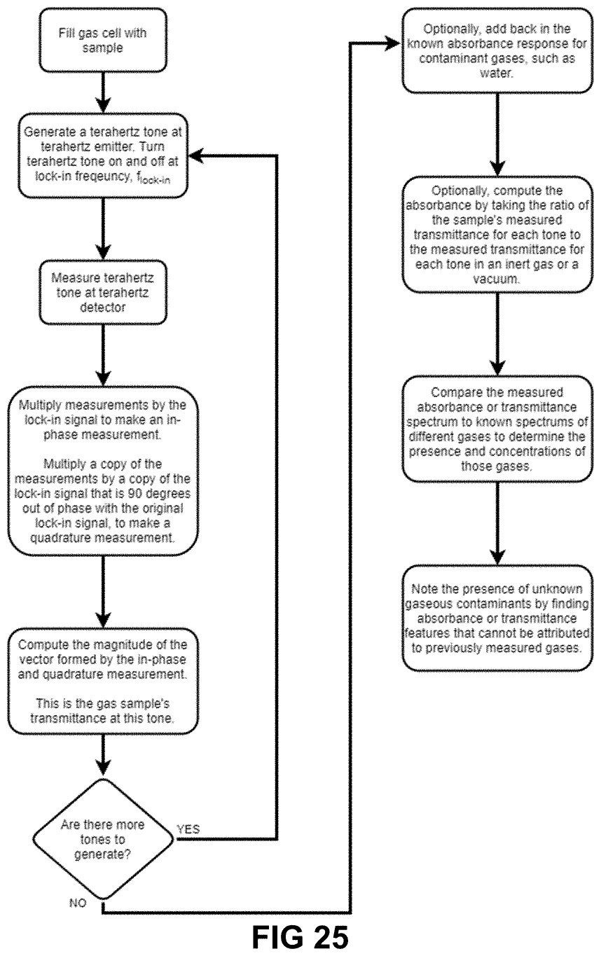

FIG. 25 is a flow diagram of a method for analyzing a gas using an electromagnetic gas spectrometer, according to one embodiment of the disclosure.

The disclosure has been sufficiently described so that a person of ordinary skill in the art can reproduce and obtain the results mentioned in the present disclosure. However, any skilled person in the field of the art of the present disclosure may be able to make modifications not described in the present application. Notwithstanding, if these modifications require a structure or manufacturing process not described in the present disclosure, the modifications should be understood to be within the scope of the disclosure.

1. An electromagnetic gas spectrometer comprising:
a gas absorption cell;
a THz broadband emitter including a chip with one or more JJs coupled to one or more antenna structures that is used to generate radiation;
a THz detector including a chip with one or more JJs coupled to one or more antenna structures that is used to measure radiation.

2. The electromagnetic gas spectrometer of claim 1 further comprising a cryogenics system.

3. The electromagnetic gas spectrometer of claim 2 wherein cryogenics system includes a cold finger that the chips are mounted on

4. The electromagnetic gas spectrometer of claim 3 further comprising a vacuum shroud
